(19) United States
(12) Patent Application Publication
(10) Pub. No.: US 2026/0190359 A1
(43) Pub. Date: Jul. 2, 2026

(54) Semiconductor device and method for manufacturing same

(71) Applicant: HANGZHOU FULLSEMI SEMICONDUCTOR CO., LTD., Hangzhou (CN)

(72) Inventors: Siling FAN, Hangzhou (CN); Wenkang CAO, Hangzhou (CN)

(73) Assignee: HANGZHOU FULLSEMI SEMICONDUCTOR CO., LTD., Hangzhou (CN)

(21) Appl. No.: 19/314,039

(22) Filed: Aug. 29, 2025

(30) Foreign Application Priority Data
Dec. 26, 2024 (CN) 2024119480907
Dec. 26, 2024 (CN) 2024119580801

(51) Int. Cl. H10D 1/66; H01L 23/48; H10D 1/00

(52) U.S. Cl. CPC H10D 1/66; H10D 1/047; H10W 20/20

(57) ABSTRACT

A semiconductor device and a method for manufacturing the same; the method includes: forming a first plate of a high-voltage capacitor; forming interlayer dielectric layers over the first plate of the high-voltage capacitor as dielectric layers of the high-voltage capacitor; etching the interlayer dielectric layers to form a deep trench; forming a first plate of the silicon capacitor on a sidewall and a bottom of the deep trench, the first plate of the silicon capacitor being connected with the first plate of the high-voltage capacitor; forming a dielectric layer of the silicon capacitor on the sidewall and the bottom of the deep trench; forming a second plate of the silicon capacitor in the deep trench; and forming a second plate of the high-voltage capacitor over the top interlayer dielectric layer. The manufacturing of the high-voltage capacitor and the silicon capacitor is integrated in one process, saving the manufacturing cost.

### CROSS REFERENCE TO RELATED APPLICATION

The present application claims the benefit of priority to Chinese Patent Application No. 202411948090.7, and Chinese Patent Application No. 202411958080.1, both entitled “SEMICONDUCTOR DEVICE AND METHOD FOR MANUFACTURING SAME”, filed with CNIPA on Dec. 26, 2024, the disclosure of which is incorporated herein by reference in its entirety for all purposes.

### FIELD OF THE INVENTION

The present disclosure generally relates to the technical field of semiconductor integrated circuits, and more particularly to a semiconductor device and a method for manufacturing the same.

### BACKGROUND OF THE INVENTION

In a chip design and manufacturing process, having a plurality of high-voltage functional devices on a single chip can improve product competitiveness.

A high-voltage capacitor (HVCAP, with a voltage of 1000V to 6000V) may be integrated into a functional semiconductor chip, or may be packaged together with the functional semiconductor chip as a capacitive isolator, which is applied to isolation of different voltage domains, including automobile isolation devices that allow secure transmission of electrical signals between different voltage domains.

In contrast to parallel-plate capacitors such as MOS capacitors and MIM capacitors, silicon capacitors (SICAP) adopt a semiconductor deep trench technology, which can greatly improve the capacitance density and capacitance, and can save a large amount of chip area. Silicon capacitors have important applications in battery management systems and drive systems of new energy vehicles due to their high stability, high reliability, high density, low thickness, low equivalent series inductance (ESL), and low equivalent series resistance (ESR).

The above two types of capacitors are capacitor devices with independent structures and functions, and it is an urgent technical problem to be solved by those skilled in the art to integrate a high-voltage capacitor and a silicon capacitor in the same process at low cost to improve product competitiveness.

### SUMMARY OF THE INVENTION

A first aspect of the present disclosure provides a method for manufacturing a semiconductor device, and the method includes:
forming a first plate of a high-voltage capacitor;
forming one or more interlayer dielectric layers over the first plate of the high-voltage capacitor as dielectric layers of the high-voltage capacitor;
etching the interlayer dielectric layers to form a deep trench;
forming a first plate of a silicon capacitor on a sidewall and a bottom of the deep trench, wherein the first plate of the silicon capacitor is connected to the first plate of the high-voltage capacitor;
forming a dielectric layer of the silicon capacitor on the sidewall and the bottom of the deep trench, wherein the dielectric layer of the silicon capacitor covers the first plate of the silicon capacitor;
forming a second plate of the silicon capacitor in the deep trench, wherein the second plate of the silicon capacitor fills the deep trench; and
forming a second plate of the high-voltage capacitor over a top interlayer dielectric layer among the one or more interlayer dielectric layers.

A second aspect of the present disclosure provides a semiconductor device manufactured by the method for manufacturing the semiconductor device, wherein the semiconductor device includes:
a first plate of a high-voltage capacitor;
one or more interlayer dielectric layers, located over the first plate of the high-voltage capacitor and serving as dielectric layers of the high-voltage capacitor, wherein a deep trench extends through the interlayer dielectric layers;
a first plate of a silicon capacitor, formed on a sidewall and a bottom of the deep trench, wherein the first plate of the silicon capacitor is connected with the first plate of the high-voltage capacitor;
a dielectric layer of the silicon capacitor, formed on the sidewall and the bottom of the deep trench, wherein the dielectric layer of the silicon capacitor covers the first plate of the silicon capacitor;
a second plate of the silicon capacitor, formed in the deep trench and filling the deep trench; and
a second plate of the high-voltage capacitor, over the top interlayer dielectric layer.

In summary, the manufacturing of the high-voltage capacitor and the silicon capacitor is integrated in one process, which saves the process steps, saves the manufacturing cost, and improves the product competitiveness. Moreover, in some embodiments, the first plate of the silicon capacitor extends along the sidewall of the deep trench to the top interlayer dielectric layer and serves as the lead-out electrode of the first plate of the silicon capacitor, so that the first plate of the silicon capacitor and the first plate of the high-voltage capacitor can be led out at the same time, which avoids the steps of separately lead-out by the metal layer and the conductive via required for the first electrode of the high-voltage capacitor, and therefore reduces the manufacturing cost.

Further, both the first plate and the second plate of the silicon capacitor are made of conductive materials, and ion implantation is not required. This removes the limitations of the ion implantation process, as the deposition process can uniformly deposit the conductive materials on the entire inner wall of the deep trench, which improves the uniformity of the first plate and reduces parasitic resistance. Additionally, since ion implantation is not required, the interlayer dielectric layers can accommodate more deep trenches, allowing for further increased integration density.

Moreover, the dielectric layer of the silicon capacitor uses oxide-nitride-oxide (ONO) or silicon nitride, which significantly increases the breakdown voltage of the capacitor, avoiding breakdown at weak points caused by dielectric defects or non-uniformity during operation.

### BRIEF DESCRIPTION OF DRAWINGS

FIG. 1 is a schematic flowchart of a method for manufacturing a semiconductor device according to an embodiment of the present disclosure.

FIG. 2 to FIG. 8 are schematic structural diagrams of steps of a method for manufacturing a semiconductor device according to an embodiment of the present disclosure.

FIG. 9 to FIG. 16 are schematic structural diagrams of steps of another method for manufacturing a semiconductor device according to an embodiment of the present disclosure.

### REFERENCE NUMERALS

100—substrate; 101—first metal layer; 102—second metal layer; 103—third metal layer; 104—fourth metal layer; 110—bottom interlayer dielectric layer; 111—first interlayer dielectric layer; 112—second interlayer dielectric layer; 113—third interlayer dielectric layer; 114—fourth interlayer dielectric layer; 115—fifth interlayer dielectric layer (top interlayer dielectric layer); 120—patterned first photoresist layer; 121—deep trench; 130—patterned second photoresist layer; 140—patterned second photoresist layer; 142—third lead-out terminal; 151—first passivation layer; 152—second passivation layer; 210—first plate of a high-voltage capacitor; 211—conductive via; 212—first lead-out terminal; 220—second plate of a high-voltage capacitor; 221—third conductive material layer; 310—first plate of a silicon capacitor; 311—first conductive material layer; 312—lead-out electrode; 320—dielectric layer of a silicon capacitor; 321—insulating material layer; 330—second plate of a silicon capacitor; 331—second conductive material layer; 332—second lead-out terminal.

### DETAILED DESCRIPTION

To make the objectives, advantages, and features of the present disclosure clearer, the present disclosure is further described in detail below with reference to the accompanying drawings and specific embodiments. It should be noted that the drawings are in a very simplified form and are not necessarily drawn to scale, and are only used to illustrate the embodiments of the present disclosure conveniently and clearly. In addition, the structures shown in the drawings are often part of actual structures. In particular, as the drawings need to show different emphasis, sometimes different proportions are used.

As used herein, the singular forms “a”, “an” and “the” include plural referents unless the content clearly dictates otherwise. As used herein, the term “or” is generally employed in its sense including “and/or” unless the content clearly dictates otherwise. As used herein, the term “several” is generally employed in its sense including “at least one” unless the content clearly dictates otherwise. As used herein, the term “at least two” is generally employed in its sense including “two or more” unless the content clearly dictates otherwise. In addition, the terms “first”, “second” and “third” are only used for descriptive purposes, and cannot be understood as indicating or implying relative importance or implicitly indicating the number of indicated technical features. Therefore, features defined as “first”, “second”, and “third” may explicitly or implicitly include one or at least two of the features, unless the content clearly indicates otherwise.

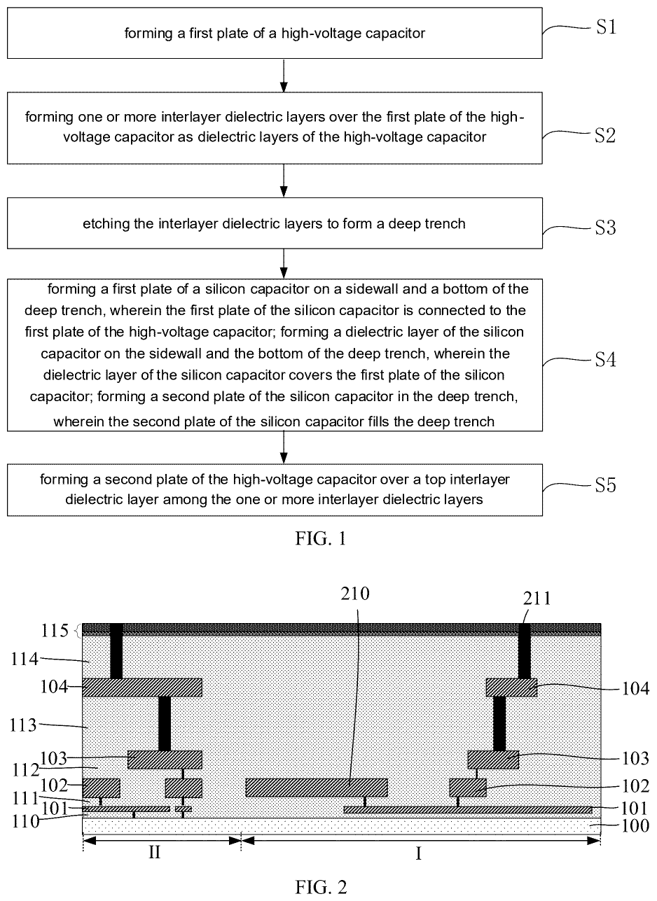

FIG. 1 is a schematic flowchart of a method for manufacturing a semiconductor device according to an embodiment of the present disclosure. As shown in FIG. 1, the method for manufacturing the semiconductor device includes the following steps.
S1: forming a first plate of a high-voltage capacitor (HVCAP);
S2: forming one or more interlayer dielectric layers over the first plate of the high-voltage capacitor as dielectric layers of the high-voltage capacitor;
S3: etching the interlayer dielectric layers to form a deep trench;
S4: forming a first plate of a silicon capacitor on a sidewall and a bottom of the deep trench, wherein the first plate of the silicon capacitor is connected to the first plate of the high-voltage capacitor; forming a dielectric layer of the silicon capacitor on the sidewall and the bottom of the deep trench, wherein the dielectric layer of the silicon capacitor covers the first plate of the silicon capacitor; forming a second plate of the silicon capacitor in the deep trench, wherein the second plate of the silicon capacitor fills the deep trench; and
S5: forming a second plate of the high-voltage capacitor over a top interlayer dielectric layer among the one or more interlayer dielectric layers.

FIG. 2 to FIG. 8 are schematic structural diagrams of steps of the method for manufacturing the semiconductor device according to an embodiment of the present disclosure. Next, the method for manufacturing the semiconductor device will be described in detail with reference to FIGS. 1, 2 to 8.

In step S1, referring to FIG. 2, the first plate 210 of the high-voltage capacitor is formed.

As an example, the step of forming the first plate 210 of the high-voltage capacitor includes S11-S14.

First, step S11 is performed to provide the substrate 100 and form a bottom interlayer dielectric layer 110 on the substrate 100.

As an example, a material of the substrate 100 may be silicon, germanium, silicon germanium, silicon carbide, gallium arsenide, indium gallium, or the like. Alternatively, it may be a silicon-on-insulator or germanium-on-insulator material, or another material, for example, a III-V compound such as gallium arsenide. As an example, the substrate 100 is a silicon substrate. A material of the bottom interlayer dielectric layer 110 may be Tetra Ethyl Ortho Silicate (TEOS), Boro-phospho-silicate Glass (BPSG), or other suitable dielectric materials, such as low-k dielectric materials, or any combination of these materials. The bottom interlayer dielectric layer 110 may be formed by using any suitable process known to a person skilled in the art, such as atomic layer deposition (ALD), chemical vapor deposition (CVD), or physical vapor deposition (PVD).

Then, step S12 is performed to form a first metal layer 101 on the bottom interlayer dielectric layer 110, and the first metal layer 101 covers a part of the bottom interlayer dielectric layer 110. A material of the first metal layer 101 includes, but is not limited to, copper, tungsten, aluminum, ruthenium, or cobalt.

Then, step S13 is performed to form a first interlayer dielectric layer 111 on the first metal layer 101. The first interlayer dielectric layer 111 covers the first metal layer 101 and the bottom interlayer dielectric layer 110. As an example, the material and forming method of the first interlayer dielectric layer 111 may be the same as the material and forming method of the bottom interlayer dielectric layer 110. Then, the first interlayer dielectric layer 111 is etched to form a through hole exposing the first metal layer 101, and a conductive material is filled in the through hole to form a conductive via.

Then, in step S14, a second metal layer 102 is formed on the first interlayer dielectric layer 111. The second metal layer 102 covers a part of the first interlayer dielectric layer 111. The second metal layer 102 is connected to the first metal layer 101 through the conductive via, and the second metal layer 102 serves as the first plate 210 of the high-voltage capacitor. As an example, referring to FIG. 2, a first part of the second metal layer 102 serves as the first plate 210 of the high-voltage capacitor, a second part of the second metal layer 102 serves as a part of the lead-out channel of the first plate 210, and a third part of the second metal layer 102 is located in a region of the substrate 100 where a semiconductor structure is formed, which will be described in detail later.

As an example, when viewed along a direction perpendicular to the substrate 100, the first plate 210 of the high-voltage capacitor covers a part of the first metal layer 101; that is, the first plate 210 of the high-voltage capacitor and the first metal layer 101 only partially overlap. The first plate 210 of the high-voltage capacitor, the dielectric layer of the high-voltage capacitor formed subsequently, and the second plate of the high-voltage capacitor together form the high-voltage capacitor. The first metal layer 101 may connect the first plate 210 of the high-voltage capacitor to an external circuit, and may also be connected to the first plate of the silicon capacitor formed subsequently.

As an example, the first metal layer 101 may also be directly used as the first plate of the high-voltage capacitor without forming the second metal layer 102 on the first interlayer dielectric layer 111.

In step S2, referring to FIG. 2, the one or more interlayer dielectric layers are formed over the first plate 210 of the high-voltage capacitor as the dielectric layers of the high-voltage capacitor. A conductive via 211 is formed in each interlayer dielectric layer, and the conductive vias 211 are connected with each other and connected to the first plate 210 of the high-voltage capacitor, forming a lead-out channel of the first plate 210 of the high-voltage capacitor.

Metal layers (for example, a third metal layer 103 and a fourth metal layer 104) may also be formed corresponding to the interlayer dielectric layers over the first plate 210 of the high-voltage capacitor (for example, the metal layers and the interlayer dielectric layers are formed in an alternated manner, or each of the metal layers are formed in one of the interlayer dielectric layers). Each of the metal layers is connected with two adjacent conductive vias 211, and the metal layers and the conductive vias 211 jointly form the lead-out channel of the first plate 210 of the high-voltage capacitor.

As an example, three interlayer dielectric layers, such as a second interlayer dielectric layer 112, a third interlayer dielectric layer 113, and a fourth interlayer dielectric layer 114, are formed over the first plate 210 of the high-voltage capacitor. The metal layers may be embedded in the interlayer dielectric layers respectively, or the metal layers and the interlayer dielectric layers are alternatively stacked, or the metal layers are partially embedded in the interlayer dielectric layers respectively while the two are alternatively arranged. Materials and forming methods of the second interlayer dielectric layer 112, the third interlayer dielectric layer 113, and the fourth interlayer dielectric layer 114 may be the same as those of the bottom interlayer dielectric layer 110 and the first interlayer dielectric layer 111.

As an example, the substrate 100 includes a first region I and a second region II. The high-voltage capacitor and the subsequent silicon capacitor are formed in the first region I, and a semiconductor structure is formed in the second region II. The substrate 100 may further include other regions, and the positions of the first region I and the second region II identified in the drawings are only exemplary. The semiconductor structure is, for example, an active device, such as a metal oxide semiconductor transistor. Several interlayer dielectric layers are formed over the second region II of the substrate 100, one or more conductive vias and one or more metal layers are formed in each of the interlayer dielectric layers of the second region, and the metal layers and the conductive vias of the second region lead out corresponding electrodes of the semiconductor structure (for example, leading out a gate, a source, and a drain of a metal oxide semiconductor transistor, respectively). As an example, four metal layers and five interlayer dielectric layers are formed over the semiconductor structure; for example, a bottom interlayer dielectric layer 110, a first interlayer dielectric layer 111, a second interlayer dielectric layer 112, a third interlayer dielectric layer 113, and a fourth interlayer dielectric layer 114, a first metal layer 101, a second metal layer 102, a third metal layer 103, and a fourth metal layer 104 are formed over the semiconductor structure.

The interlayer dielectric layers, metal layers and conductive vias over the first region I of the substrate 100 are formed synchronously with corresponding interlayer dielectric layers, metal layers and conductive vias over the second region II of the substrate 100. For instance, the bottommost layer over the first region I is formed synchronously with the bottommost layer over the second region II, followed by the synchronous, layer-by-layer formation of subsequent layers. More specifically, as an example, the layers over the substrate are formed without regard to the regions, which serve merely as conceptual divisions. For example, the first plate 210 of the high-voltage capacitor is formed synchronously with the metal layer of the second region II in the same layer (for example, the second metal layer 102), each of the dielectric layers of the high-voltage capacitor is formed synchronously with one of the interlayer dielectric layers of the second region II located in the same layer (for example, in the second region II, three interlayer dielectric layers are further formed over the second metal layer 102, and the dielectric layers of the high-voltage capacitor include three interlayer dielectric layers; the number of interlayer dielectric layers included in the dielectric layers of the high-voltage capacitor is the same as the number of interlayer dielectric layers over the second metal layer 102 in the second region II, and the number is not limited to 3), and the lead-out channel is formed synchronously with the metal layer and the conductive via of the second region II in the same layer (that is, when the corresponding electrode of the semiconductor structure is led out in the second region II, the lead-out channel is also formed in the first region I to lead out the first metal layer 101, which is equivalent to leading out the first plate 210).

Referring to FIG. 2, the bottom interlayer dielectric layer 110 is formed on the substrate 100. A conductive via is formed in the bottom interlayer dielectric layer 110. The conductive via is only located in the second region II for connecting the electrodes of the semiconductor structure. Then multiple first metal layers 101 located in the same layer are formed, and the first metal layers 101 are located in different regions. For example, the first metal layer 101 located in the first region I serves as a connection layer between the first plate of the high-voltage capacitor and the first plate of the silicon capacitor, and the first metal layers 101 located in the second region II are used to connect the conductive via, thereby connecting different electrodes of the semiconductor structure. Then, the first interlayer dielectric layer 111 is formed, and then multiple conductive vias are formed in the first interlayer dielectric layer 111, where different conductive vias are connected to different or the same first metal layer 101, and so on, and the same interlayer dielectric layer (or the same metal layer or conductive via located in the same layer) formed over different regions of the substrate 100 is formed in the same step.

As an example, a fifth interlayer dielectric layer (a top interlayer dielectric layer) 115 is further formed on the fourth interlayer dielectric layer 114, and the fifth interlayer dielectric layer 115 includes a silicon oxynitride layer and a silicon nitride layer that are sequentially located over the fourth interlayer dielectric layer 114, to improve a voltage withstand performance of the high-voltage capacitor.

As an example, materials of the first plate 210 of the high-voltage capacitor are the same as materials of the second metal layer 102, and materials of the dielectric layers of the high-voltage capacitor are determined by materials of respective interlayer dielectric layers. Exemplarily, materials of the first plate 210 of the high-voltage capacitor include, but are not limited to, copper, tungsten, aluminum, ruthenium or cobalt, and materials of the dielectric layer of the high-voltage capacitor may be ethyl silicate, boro-phospho-silicate glass, or other suitable dielectric materials, such as low-k dielectric materials or any combination of these materials.

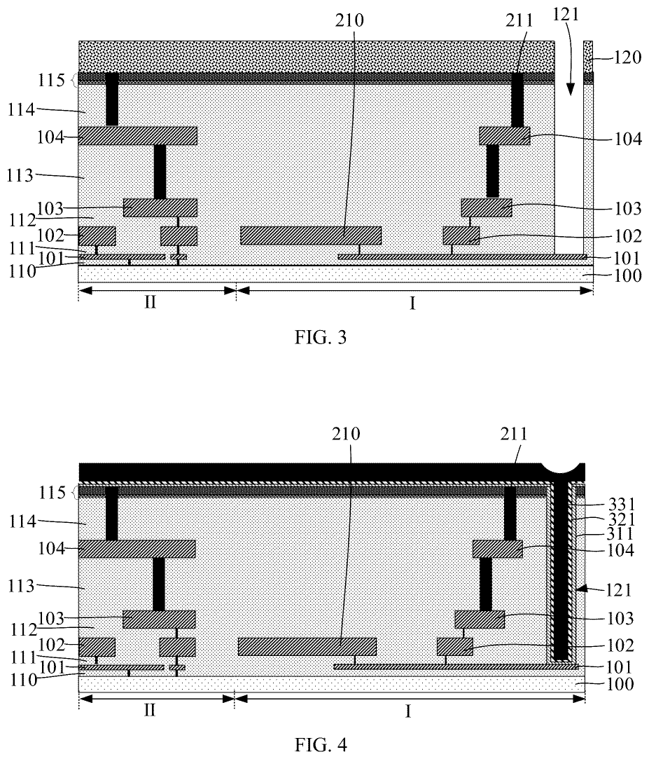

In step S3, referring to FIG. 3, the interlayer dielectric layers are etched to form the deep trench 121.

As an example, a photoresist layer (referred to as a first photoresist layer for distinguishing from a subsequent photoresist layer) is formed on the top interlayer dielectric layer (that is, the fifth interlayer dielectric layer 115). The first photoresist layer is exposed and developed to form a patterned first photoresist layer 120, all the interlayer dielectric layers are etched by using the patterned first photoresist layer 120 as a mask to form the deep trench 121, and then the patterned first photoresist layer 120 is removed. As an example, all the interlayer dielectric layers are etched until the first metal layer 101 is exposed, that is, the fifth interlayer dielectric layer 115, the fourth interlayer dielectric layer 114, the third interlayer dielectric layer 113, the second interlayer dielectric layer 112, and the first interlayer dielectric layer 111 (that is, all the interlayer dielectric layers located above the first metal layer 101) are etched to form the deep trench 121 (partially) exposing the first metal layer 101.

It should be noted that the deep trench 121, the lead-out channel, and the first plate 210 of the high-voltage capacitor are all located at different positions of the first region I; the deep trench 121 is provided with a plurality of laminated interlayer dielectric layers; the first plate 210 of the high-voltage capacitor is also provided with only a plurality of laminated interlayer dielectric layers above the first plate 210; for the lead-out channel, it is not only provided with a plurality of laminated interlayer dielectric layers, but also a metal layer and a conductive via above the metal layer corresponding to each interlayer dielectric layer to connect the first metal layer 101 to the upper surface of the top interlayer dielectric layer 115.

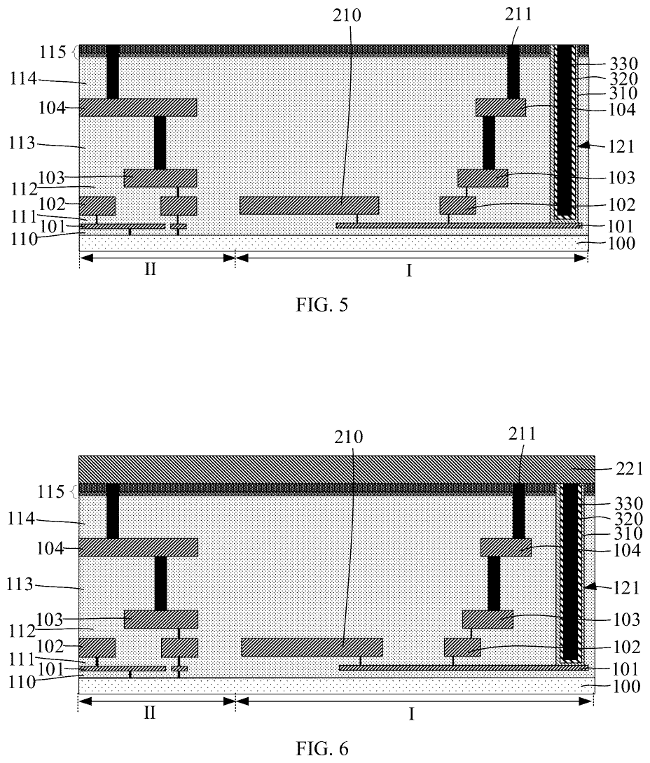

In step S4, referring to FIG. 4 and FIG. 5, the first plate 310 of the silicon capacitor is formed on the sidewall and the bottom of the deep trench 121, and the first plate 310 of the silicon capacitor is connected with the first plate 210 of the high-voltage capacitor; the dielectric layer 320 of the silicon capacitor is formed on the sidewall and the bottom of the deep trench 121, and the dielectric layer 320 of the silicon capacitor covers the first plate 310 of the silicon capacitor; and the second plate 330 of the silicon capacitor is formed in the deep trench 121, and the second plate 330 of the silicon capacitor fills the deep trench.

As an example, first, a first conductive material layer 311 is formed, wherein the first conductive material layer 311 covers the sidewall and the bottom of the deep trench 121, and covers the top surface of the fifth interlayer dielectric layer 115; then, an insulating material layer 321 is formed, wherein the insulating material layer 321 covers the sidewall and the bottom of the deep trench 121, and covers the top surface of the fifth interlayer dielectric layer 115, that is, the insulating material layer 321 covers the first conductive material layer 311; and then, a second conductive material layer 331 is formed, wherein the second conductive material layer 331 fills the deep trench 121 and covers the fifth interlayer dielectric layer 115 (specifically, covers the insulating material layer 321 on the fifth interlayer dielectric layer 115), to form the structure shown in FIG. 4.

Then, referring to FIG. 5, planarization, such as chemical mechanical polishing, is performed until the fifth interlayer dielectric layer 115 is exposed (that is, until the top interlayer dielectric layer is exposed); then, a first conductive layer covering the sidewall and the bottom of the deep trench 121 is formed in the deep trench 12; then, an insulating layer covering the first conductive layer and covering the sidewall and the bottom of the deep trench 121 is formed; then a second conductive layer fills the deep trench 121. The first conductive layer serves as the first plate 310 of the silicon capacitor, the insulating layer serves as the dielectric layer 320 of the silicon capacitor, and the second conductive layer serves as the second plate 330 of the silicon capacitor. It should be noted that when the chemical mechanical polishing stops at the fifth interlayer dielectric layer 115, the loss of the fifth interlayer dielectric layer 115 needs to be controlled to prevent the thickness change of the fifth interlayer dielectric layer 115 from affecting the voltage resistance of the high-voltage capacitor.

As an example, materials of the first conductive material layer 311 include, but are not limited to, titanium nitride, materials of the second conductive material layer 331 include, but are not limited to, tungsten, the insulating material layer 321 includes a silicon nitride layer or a stacked structure including a silicon oxide layer, a silicon nitride layer, and another silicon oxide layer (collectively referred to as ONO), that is, materials of the insulating material layer 321 include, but are not limited to, ONO or silicon nitride; that is, in the silicon capacitor, materials of the first plate 310 of the silicon capacitor include, but are not limited to, titanium nitride, materials of the second plate 330 of the silicon capacitor include, but are not limited to, tungsten, and materials of the dielectric layer 320 of the silicon capacitor include, but are not limited to, ONO or silicon nitride. The first conductive material layer 311, the insulating material layer 321, and the second conductive material layer 331 may be formed by deposition, such as atomic layer deposition, chemical vapor deposition, or physical vapor deposition.

As an example, both the first plate 310 and the second plate 330 of the silicon capacitor are made of a conductive material, and ion implantation is not required. This removes the limitations of the ion implantation process, as the deposition process can uniformly deposit the conductive materials on the entire inner wall of the deep trench. This improves the uniformity of the first plate and reduces parasitic resistance. Additionally, since ion implantation is not required, the interlayer dielectric layers can accommodate more deep trenches, allowing for further increased integration density.

Moreover, the dielectric layer 320 of the silicon capacitor uses oxide-nitride-oxide (ONO) or silicon nitride, which significantly increases the breakdown voltage of the capacitor, avoiding breakdown at weak points caused by dielectric defects or non-uniformity during operation.

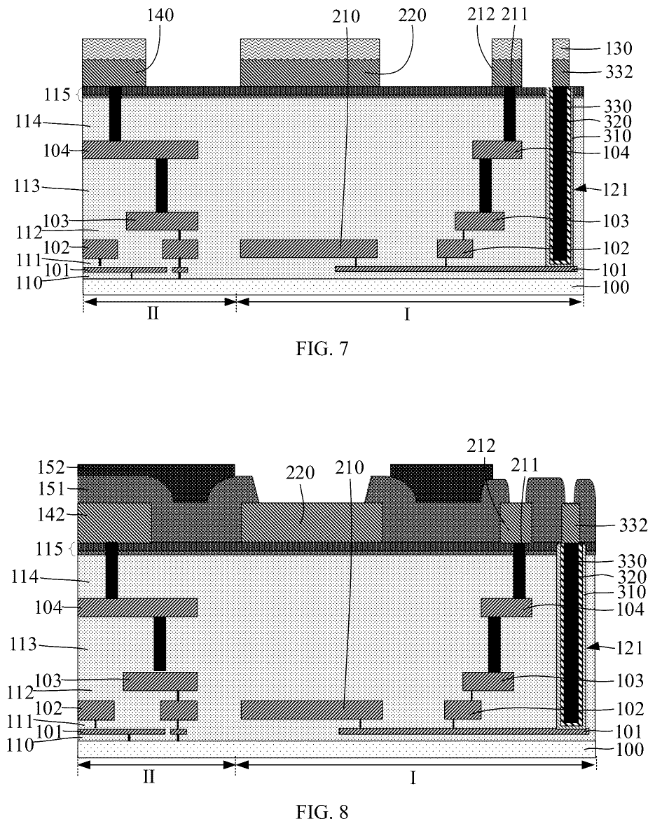

In step S5, referring to FIG. 7, the second plate 220 of the high-voltage capacitor is formed on the top interlayer dielectric layer 115.

Exemplarily, first, referring to FIG. 6, a conductive material layer (in order to distinguish from the first conductive material layer and the second conductive material layer, it is referred to as a third conductive material layer 221) is formed, and the third conductive material layer 221 covers the top interlayer dielectric layer, specifically covers the fifth interlayer dielectric layer 115, and also covers the conductive via 211 in the top interlayer dielectric layer and the silicon capacitor.

Then, referring to FIG. 7, the third conductive material layer 221 is etched until the top interlayer dielectric layer is exposed; specifically, a second photoresist layer is formed on the third conductive layer 221, the second photoresist layer is exposed and developed to form a patterned second photoresist layer 130, the third conductive material layer 221 is then etched by using the patterned second photoresist layer 130 as a mask until a part of the top interlayer dielectric layer is exposed, and a part of the third conductive material layer 221 is retained after the etching. The third conductive material layer located directly above the first plate 210 of the high-voltage capacitor is retained as the second plate 220 of the high-voltage capacitor; the third conductive material layer located above the lead-out channel is retained as a first lead-out terminal 212, leading out the first plate 210 of the high-voltage capacitor and the first plate 310 of the silicon capacitor; the third conductive material layer located above the second plate 330 of the silicon capacitor is retained as a second lead-out terminal 332, leading out the second plate 330 of the silicon capacitor; the third conductive material layer above the conductive via in the second region II is retained as a third lead-out terminal 142, leading out an electrode of the semiconductor structure. Then, the patterned second photoresist layer 130 is removed.

As an example, materials of the third conductive material layer 221 include, but are not limited to, copper, tungsten, aluminum, ruthenium, or cobalt.

In addition, as an example, when the third conductive material layer 221 is etched, dimensions of the remaining portions of the third conductive material layer 221 need to be controlled, to prevent the first plate 310 of the silicon capacitor from being short-circuited with the second plate 330 of the silicon capacitor.

Referring to FIG. 8, after forming the second plate 220 of the high-voltage capacitor, the method further includes: forming a passivation layer, wherein the passivation layer covers the portions of the top interlayer dielectric layer exposed by the lead-out terminals and partially exposes the lead-out terminals. As an example, referring to FIG. 8, the passivation layer includes a first passivation layer 151 and a second passivation layer 152, a material of the first passivation layer 151 includes silicon oxynitride, and a material of the second passivation layer 152 includes polyimide(PI) . As another example, only one passivation layer is formed, and the passivation layer may be made of silicon oxynitride or PI.

In the presently disclosed method for manufacturing the semiconductor device, a first plate 210 of a high-voltage capacitor is first formed. One or more interlayer dielectric layers are formed on the first plate 210 to serve as dielectric layers of the high-voltage capacitor. Conductive vias 211 are formed in the interlayer dielectric layers, with each layer having one or more conductive vias. The conductive vias 211 are connected with each other and connected with the first plate 210, thereby forming a lead-out channel of the first plate 210. Then all the interlayer dielectric layers are etched to form a deep trench 121. A first plate 310 of the silicon capacitor is formed on a sidewall and a bottom of the deep trench 121, and the first plate 310 of the silicon capacitor is connected with the first plate 210 of the high-voltage capacitor. A dielectric layer 320 of the silicon capacitor is formed on the sidewall and the bottom of the deep trench 121, and the dielectric layer 320 of the silicon capacitor covers the first plate 310 of the silicon capacitor. A second plate 330 of the silicon capacitor is formed in the deep trench 121, and the second plate 330 of the silicon capacitor fills the deep trench 121. Then a second plate 220 of the high-voltage capacitor is formed over the top interlayer dielectric layer. In the present disclosure, the manufacturing of the high-voltage capacitor and the silicon capacitor is integrated in one process, which saves the process steps, saves the manufacturing cost, and improves the product competitiveness.

Correspondingly, the present disclosure further provides a semiconductor device, which may or may not be manufactured by the method for manufacturing the semiconductor device as described above.

Referring to FIG. 8, the semiconductor device includes:
a first plate 210 of a high-voltage capacitor;
one or more interlayer dielectric layers over the first plate 210 of the high-voltage capacitor as dielectric layers of the high-voltage capacitor, wherein conductive vias 211 are formed in the interlayer dielectric layers, each of which has one or more of the conductive vias formed therein, the conductive vias 211 are connected with each other and connected with the first plate 210 of the high-voltage capacitor, forming a lead-out channel of the first plate 210 of the high-voltage capacitor, and a deep trench 121 extending through the interlayer dielectric layers is formed in the interlayer dielectric layers;
a first plate 310 of a silicon capacitor, formed on a sidewall and a bottom of the deep trench 121, wherein the first plate 310 of the silicon capacitor is connected with the first plate 210 of the high-voltage capacitor;
a dielectric layer 320 of the silicon capacitor, formed on the sidewall and the bottom of the deep trench 121 and covering the first plate 310 of the silicon capacitor;
a second plate 330 of the silicon capacitor, formed in the deep trench 121 and filling the deep trench 121; and
a second plate 220 of the high-voltage capacitor, over a top interlayer dielectric layer.

As an example, materials of the first plate 310 of the silicon capacitor include, but are not limited to, titanium nitride. Materials of the second plate 330 of the silicon capacitor include, but are not limited to, tungsten. Further, both the first plate 310 and the second plate 320 of the silicon capacitor are made of conductive materials, and ion implantation is not required. This removes the limitations of the ion implantation process, as the deposition process can uniformly deposit the conductive materials on the entire inner wall of the deep trench, which improves the uniformity of the first plate and reduces parasitic resistance. Additionally, since ion implantation is not required, the interlayer dielectric layers can accommodate more deep trenches, allowing for further increased integration density.

As an example, the dielectric layer 320 of the silicon capacitor uses oxide-nitride-oxide (ONO) or silicon nitride, which significantly increases the breakdown voltage of the capacitor, avoiding breakdown at weak points caused by dielectric defects or non-uniformity during operation.

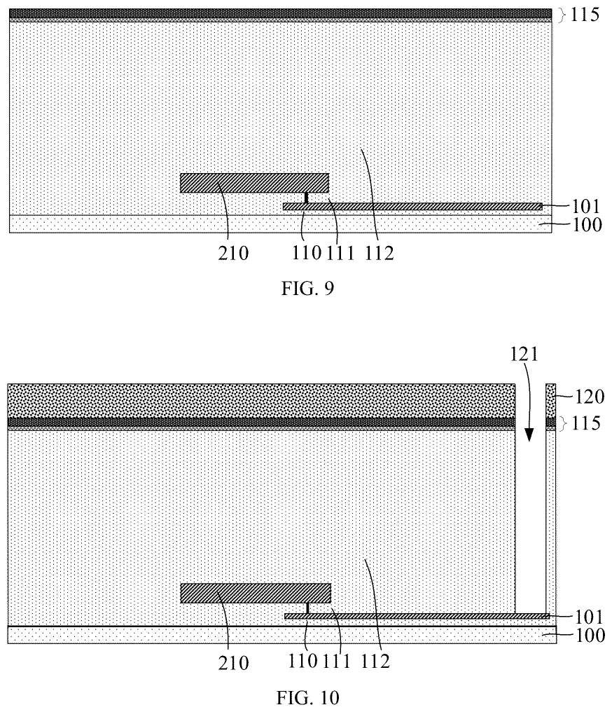

FIG. 9 to FIG. 16 are schematic structural diagrams of steps of another method for manufacturing a semiconductor device according to an embodiment of the present disclosure. Next, the method will be described in detail with reference to FIGS. 1, 9 to 16. One main difference between the method described in FIG. 2 to FIG. 8 and the method described in FIG. 9 to FIG. 16 is that: in the former, the first plate of the high-voltage capacitor is connected with the first plate of the high-voltage capacitor through the lead-out channel formed by the conductive vias and the metal layers; in the latter, the first plate of the silicon capacitor extends along the sidewall of the deep trench to the interlayer dielectric layer, and the first plate of the silicon capacitor is directly used as the lead-out electrode, and connected with the first plate of the high-voltage capacitor at the same time without an additional lead-out channel.

In step S1, referring to FIG. 9, a first plate 210 of a high-voltage capacitor is formed.

As an example, the step of forming the first plate 210 of the high-voltage capacitor includes:

First, step S11′ is performed to provide the substrate 100 and form a bottom interlayer dielectric layer 110 over the substrate 100.

Then, step S12′ is performed to form a first metal layer 101 on the bottom interlayer dielectric layer 110, and the first metal layer 101 covers a part of the bottom interlayer dielectric layer 110.

Then, step S13′ is performed to form a first interlayer dielectric layer 111 over the first metal layer 101, and the first interlayer dielectric layer 111 covers the first metal layer 101 and the bottom interlayer dielectric layer 110. As an example, materials and forming method of the first interlayer dielectric layer 111 may be the same as those of the bottom interlayer dielectric layer 110. Then, the first interlayer dielectric layer 111 is etched to form a through hole exposing the first metal layer 101, and a conductive material is filled in the through hole to form a conductive via.

Then, step S14′ is performed to form the first plate 210 of the high-voltage capacitor over the first interlayer dielectric layer 111, the first plate 210 of the high-voltage capacitor covers a part of the first interlayer dielectric layer 111, and the first plate 210 of the high-voltage capacitor is connected to the first metal layer 101 through the conductive via.

As an example, when viewed along a direction perpendicular to the substrate 100, the first plate 210 of the high-voltage capacitor covers a part of the first metal layer 101, that is, the first plate 210 of the high-voltage capacitor and the first metal layer 101 only partially overlap; the first plate 210 of the high-voltage capacitor, the dielectric layer of the high-voltage capacitor formed subsequently, and the second plate of the high-voltage capacitor together form the high-voltage capacitor; the first metal layer 101 may connect the first plate 210 of the high-voltage capacitor to an external circuit, and may also be connected to the first plate of the silicon capacitor formed subsequently.

As another example, the first plate 210 of the high-voltage capacitor may also be directly formed on the bottom interlayer dielectric layer 110 without forming the first metal layer 101, and subsequently, the first plate of the silicon capacitor may be directly connected to the first plate 210 of the high-voltage capacitor.

In step S2, referring to FIG. 9, one or more interlayer dielectric layers is formed over the first plate 210 of the high-voltage capacitor as dielectric layers of the high-voltage capacitor.

As an example, one interlayer dielectric layer, such as the second interlayer dielectric layer 112, may be formed over the first plate 210 of the high-voltage capacitor. Materials and forming methods of the second interlayer dielectric layer 112, the bottom interlayer dielectric layer 110, and the first interlayer dielectric layer 111 may be the same.

As an example, a top interlayer dielectric layer 115 may also be formed over the second interlayer dielectric layer 112. The top interlayer dielectric layer 115 may include a silicon oxynitride layer and a silicon nitride layer to improve the voltage withstand performance of the high-voltage capacitor.

As an example, a metal interconnection structure may be formed while the first plate 210 of the high-voltage capacitor and the one or more interlayer dielectric layers are being formed. Exemplarily, the substrate 100 may include a first region and a second region, the high-voltage capacitor and the subsequently formed silicon capacitor are located in the first region, a semiconductor structure may be formed in the second region, and the semiconductor structure is, for example, an active device such as a metal oxide semiconductor transistor. The metal interconnection structure includes multiple interlayer dielectric layers; one or more conductive vias are formed in each of the interlayer dielectric layers, and metal layers are formed corresponding to respective interlayer dielectric layers (each of the former is embedded in one of the latter, or the two are alternated); the metal layers and the conductive vias lead out corresponding electrodes of the semiconductor structure (for example, leading out a gate, a source, and a drain of a metal oxide semiconductor transistor, respectively). While the metal interconnection structure is being formed in the second region, the first plate 210 of the high-voltage capacitor and interlayer dielectric layers may be simultaneously formed in the first region (layer by layer), thereby reducing process steps and manufacturing costs. The first plate 210 and the one or more interlayer dielectric layers of the high-voltage capacitor may also be formed independently of the metal interconnection structure.

In step S3, referring to FIG. 10, the interlayer dielectric layer is etched to form a deep trench 121.

As an example, a photoresist layer (referred to as a first photoresist layer for distinguishing from a subsequent photoresist layer) is formed on the top interlayer dielectric layer 115. The first photoresist layer is exposed and developed to form a patterned first photoresist layer 120. All the interlayer dielectric layers are etched by using the patterned first photoresist layer 120 as a mask to form the deep trench 121, and then the patterned first photoresist layer 120 is removed. As an example, all the interlayer dielectric layers are etched until the first metal layer 101 is exposed, that is, the top interlayer dielectric layer 115, the second interlayer dielectric layer 112, and the first interlayer dielectric layer 111 (that is, all the interlayer dielectric layers located above the first metal layer 101) are etched to form the deep trench 121 (partially) exposing the first metal layer 101.

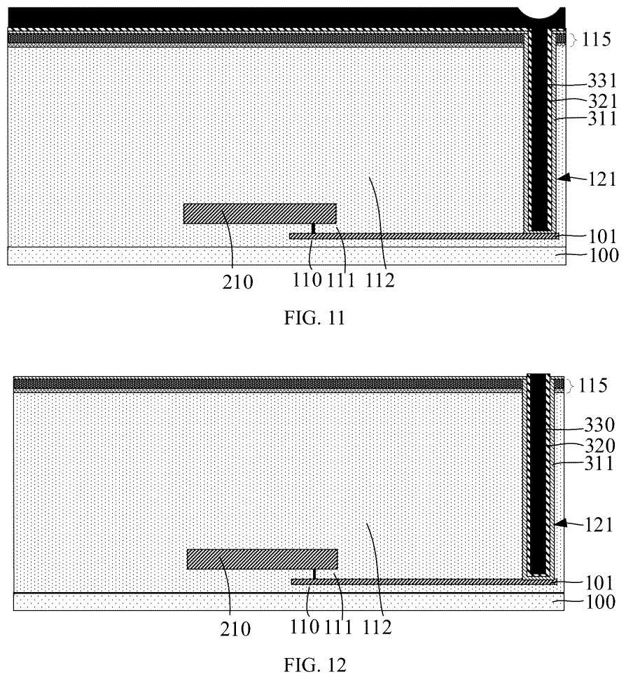

In step S4, referring to FIG. 11 to FIG. 13, the first plate 310 of the silicon capacitor is formed on a sidewall and a bottom of the deep trench 121, and the first plate 310 of the silicon capacitor is connected with the first plate 210 of the high-voltage capacitor; the dielectric layer 320 of the silicon capacitor is formed on the sidewall and the bottom of the deep trench 121, and the dielectric layer 320 of the silicon capacitor covers the first plate 310 of the silicon capacitor; and the second plate 330 of the silicon capacitor is formed in the deep trench 121, and the second plate 330 of the silicon capacitor fills the deep trench 121. The first plate 310 of the silicon capacitor extends along the sidewall of the deep trench 121 to the top interlayer dielectric layer to serve as the lead-out electrode 312 of the first plate 310 of the silicon capacitor.

As an example, referring to FIG. 11, first, a first conductive material layer 311 is formed, wherein the first conductive material layer 311 covers the sidewall and the bottom of the deep trench 121, and covers the top surface of the top interlayer dielectric layer 115; then, an insulating material layer 321 is formed, wherein the insulating material layer 321 covers the sidewall and the bottom of the deep trench 121, and covers the top surface of the top interlayer dielectric layer 115, that is, the insulating material layer 321 covers the first conductive material layer 311; and then, a second conductive material layer 331 is formed, wherein the second conductive material layer 331 fills the deep trench 121 and covers the top interlayer dielectric layer 115 (specifically, covers the insulating material layer 321 on the top interlayer dielectric layer 115).

Then, referring to FIG. 11 and FIG. 12, planarization, for example, chemical mechanical polishing, is performed until the first conductive material layer 311 is exposed, then the insulating material layer 321 on the top surface of the top interlayer dielectric layer 115 is removed, and only the insulating material layer 321 on the sidewall and the bottom of the deep trench 121 is retained as the dielectric layer 320 of the silicon capacitor; the second conductive material layer 331 on the surface of the top interlayer dielectric layer 115 is also removed, and only the second conductive material layer 331 in the deep trench 121 is retained as the second plate 330 of the silicon capacitor.

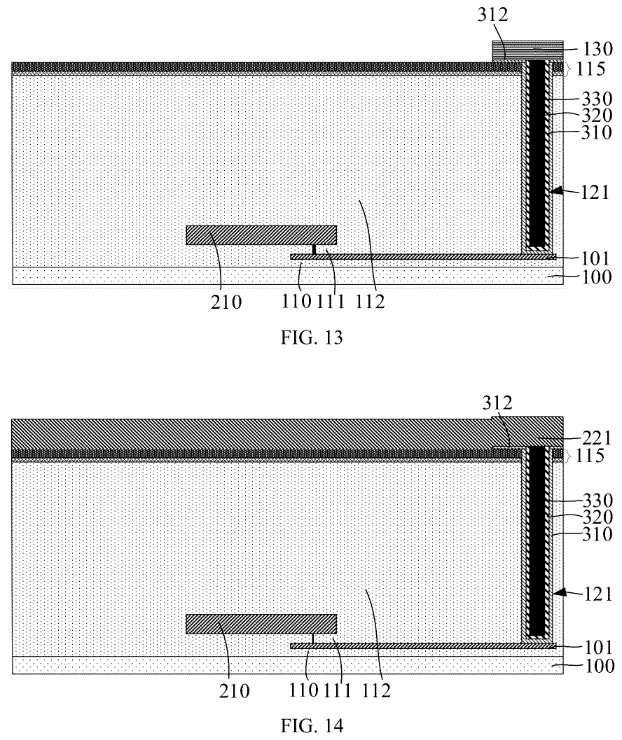

Then, referring to FIG. 13, a second photoresist layer is formed, the second photoresist layer is exposed and developed to form a patterned second photoresist layer 130, then the first conductive material layer 311 is etched with the patterned second photoresist layer 130 as a mask until a part of the top interlayer dielectric layer 115 is exposed, the first plate 310 of the silicon capacitor is formed on the sidewall and the bottom of the deep trench 121, and the lead-out electrode 312 connected with the first plate 310 of the silicon capacitor is formed on the top interlayer dielectric layer 115. As an example, the first plate 310 of the silicon capacitor and the first plate 210 of the high-voltage capacitor are connected through the first metal layer 101, so the lead-out electrode 312 serves as a common lead-out electrode of the first plate 310 of the silicon capacitor and the first plate 210 of the high-voltage capacitor. Then, the patterned second photoresist layer 130 is removed.

As an example, the first plate 310 of the silicon capacitor extends along the sidewall of the deep trench 121 to the top interlayer dielectric layer to serve as the lead-out electrode 312 of the first plate 310 of the silicon capacitor, so that the first plate 310 of the silicon capacitor and the first plate 210 of the high-voltage capacitor can be led out at the same time, which avoids the steps of separately lead-out by the metal layer and the conductive via required for the first electrode of the high-voltage capacitor, and therefore reduces the manufacturing cost.

As an example, when the first conductive material layer 311 is etched, the etching amount needs to be controlled, and too much etching may cause a change in a thickness of the top interlayer dielectric layer 115 (that is, a thickness of the dielectric layers of the high-voltage capacitor), thereby affecting voltage withstand performance of the high-voltage capacitor.

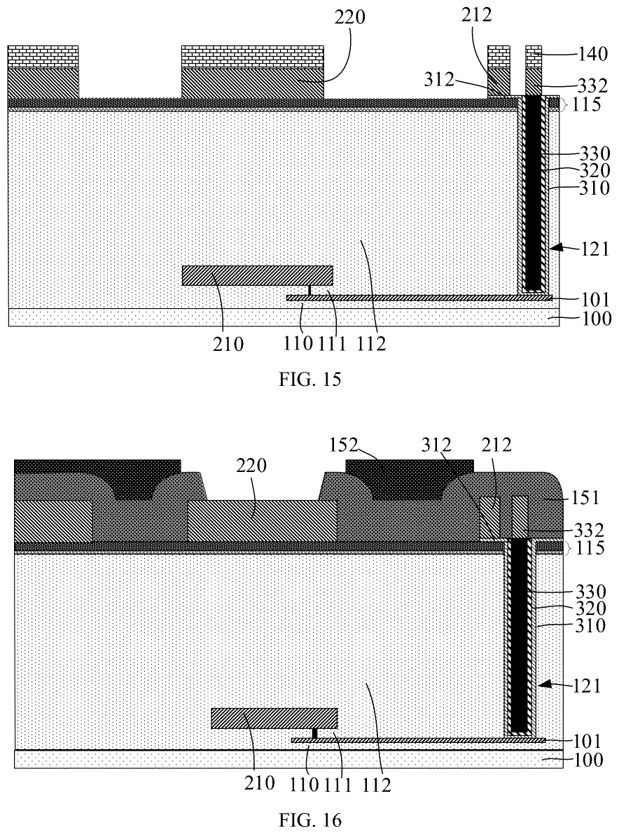

In step S5, referring to FIG. 15, the second plate 220 of the high-voltage capacitor is formed on the top interlayer dielectric layer.

Exemplarily, first, referring to FIG. 14, a conductive material layer (in order to distinguish from the first conductive material layer 311 and the second conductive material layer 331, it is referred to as a third conductive material layer 221) is formed, and the third conductive material layer 221 covers the top interlayer dielectric layer, specifically covers the top interlayer dielectric layer 115, and also covers the lead-out electrode 312.

Then, referring to FIG. 15, the third conductive material layer 221 is etched until the top interlayer dielectric layer is exposed; specifically, a third photoresist layer is formed on the third conductive layer 221, the third photoresist layer is exposed and developed to form a patterned third photoresist layer 140, the third conductive material layer 221 is etched by using the patterned third photoresist layer 140 as a mask until a part of the top interlayer dielectric layer is exposed, and a part of the third conductive material layer 221 is retained. The third conductive material layer located directly above the first plate 210 of the high-voltage capacitor is retained as the second plate 220 of the high-voltage capacitor; the third conductive material layer located above the lead-out electrode 312 is retained as a first lead-out terminal 212, leading out the first plate 210 of the high-voltage capacitor and the first plate 310 of the silicon capacitor; and the third conductive material layer located above the second plate 330 of the silicon capacitor is retained as a second lead-out terminal 332, leading out the second plate 330 of the silicon capacitor.

In addition, as an example, when the third conductive material layer 221 is etched, dimensions of the remaining portions of the third conductive material layer 221 need to be controlled, to prevent the first plate 310 of the silicon capacitor from being short-circuited with the second plate 330 of the silicon capacitor.

Referring to FIG. 16, after forming the second plate 220 of the high-voltage capacitor, the method further includes: forming a passivation layer, wherein the passivation layer covers the portions of the top interlayer dielectric layer exposed by the second plate 220 of the high-voltage capacitor and the lead-out terminals, and exposes the second plate 220 of the high-voltage capacitor and the lead-out terminals. As an example, referring to FIG. 16, the passivation layer includes a first passivation layer 151 and a second passivation layer 152, a material of the first passivation layer 151 includes silicon oxynitride, and a material of the second passivation layer 152 includes PI. As another example, only one passivation layer is formed, and the passivation layer may be made of silicon oxynitride or PI.

In the presently disclosed method for manufacturing the semiconductor device, a first plate 210 of a high-voltage capacitor is first formed. Then one or more interlayer dielectric layers are formed on the first plate 210 as dielectric layers of the high-voltage capacitor. Then all the interlayer dielectric layers are etched to form a deep trench 121. Then a first plate 310 of the silicon capacitor is formed on a sidewall and a bottom of the deep trench 121, and the first plate 310 of the silicon capacitor is connected with the first plate 210 of the high-voltage capacitor. The first plate 310 of the silicon capacitor extends along the sidewall of the deep trench 121 to a top interlayer dielectric layer, serving as a lead-out electrode 312 of the first plate 310 of the silicon capacitor. A dielectric layer 320 of the silicon capacitor is formed on the sidewall and the bottom of the deep trench 121, and the dielectric layer 320 of the silicon capacitor covers the first plate 310 of the silicon capacitor. A second plate 330 of the silicon capacitor is formed in the deep trench 121, and the second plate 330 of the silicon capacitor fills the deep trench 121. Then a second plate 220 of the high-voltage capacitor is formed over the top interlayer dielectric layer. In the present disclosure, the manufacturing of the high-voltage capacitor and the silicon capacitor is integrated in one process, which saves the process steps, saves the manufacturing cost, and improves the product competitiveness.

Correspondingly, the present disclosure further provides a semiconductor device, which may or may not be manufactured by the method for manufacturing the semiconductor device as described above.

Referring to FIG. 16, the semiconductor device includes:
a first plate 210 of a high-voltage capacitor;
one or more interlayer dielectric layers, located over the first plate 210 of the high-voltage capacitor and serving as dielectric layers of the high-voltage capacitor, wherein a deep trench 121 extends through the interlayer dielectric layers;
a first plate 310 of the silicon capacitor, formed on a sidewall and a bottom of the deep trench 121, wherein the first plate 310 of the silicon capacitor is connected with the first plate 210 of the high-voltage capacitor, and the first plate 310 of the silicon capacitor extends along the sidewall of the deep trench 121 to a top interlayer dielectric layer to serve as a lead-out electrode 312 of the first plate 310 of the silicon capacitor;
a dielectric layer 320 of the silicon capacitor, formed on the sidewall and the bottom of the deep trench 121 and covering the first plate 310 of the silicon capacitor;
a second plate 330 of the silicon capacitor, formed in the deep trench 121 and filling the deep trench 121; and
a second plate 220 of the high-voltage capacitor, formed over the top interlayer dielectric layer.

Unless otherwise indicated, components, layers, etc. having the same reference numerals in FIGS. 9-16 and 2-8 have the same material definitions.

In summary, in the presently disclosed semiconductor device and method for manufacturing the same: a first plate of a high-voltage capacitor is first formed; then interlayer dielectric layers are formed over the first plate of the high-voltage capacitor as dielectric layers of the high-voltage capacitor; then the interlayer dielectric layers are etched to form a deep trench; a first plate of the silicon capacitor is formed on a sidewall and a bottom of the deep trench, the first plate of the silicon capacitor being connected with the first plate of the high-voltage capacitor; a dielectric layer of the silicon capacitor is formed on the sidewall and the bottom of the deep trench; a second plate of the silicon capacitor is formed in the deep trench; and a second plate of the high-voltage capacitor is formed over the top interlayer dielectric layer. Moreover, in some embodiments, the first plate of the silicon capacitor extends along the sidewall of the deep trench to the top interlayer dielectric layer and serves as the lead-out electrode of the first plate of the silicon capacitor, so that the first plate of the silicon capacitor and the first plate of the high-voltage capacitor can be led out at the same time, which avoids the steps of separately lead-out by the metal layer and the conductive via required for the first electrode of the high-voltage capacitor, and therefore reduces the manufacturing cost.

In the present disclosure, the manufacturing of the high-voltage capacitor and the silicon capacitor is integrated in one process, which saves the process steps, saves the manufacturing cost, and improves the product competitiveness.

Further, both the first plate and the second plate of the silicon capacitor are made of conductive materials, and ion implantation is not required. This removes the limitations of the ion implantation process, as the deposition process can uniformly deposit the conductive materials on the entire inner wall of the deep trench, which improves the uniformity of the first plate and reduces parasitic resistance. Additionally, since ion implantation is not required, the interlayer dielectric layers can accommodate more deep trenches, allowing for further increased integration density.

Moreover, the dielectric layer of the silicon capacitor uses ONO or silicon nitride, which significantly increases the breakdown voltage of the capacitor, avoiding breakdown at weak points caused by dielectric defects or non-uniformity during operation.

The above description is only the description of the preferred embodiments of the present disclosure and is not intended to limit the scope of the present disclosure, and any changes and modifications made by those skilled in the art according to the above disclosure fall within the scope of the present disclosure.

1. A method for manufacturing a semiconductor device, comprising:
forming a first plate of a high-voltage capacitor;
forming one or more interlayer dielectric layers over the first plate of the high-voltage capacitor as dielectric layers of the high-voltage capacitor;
etching the interlayer dielectric layers to form a deep trench;
forming a first plate of a silicon capacitor on a sidewall and a bottom of the deep trench, wherein the first plate of the silicon capacitor is connected to the first plate of the high-voltage capacitor;
forming a dielectric layer of the silicon capacitor on the sidewall and the bottom of the deep trench, wherein the dielectric layer of the silicon capacitor covers the first plate of the silicon capacitor;
forming a second plate of the silicon capacitor in the deep trench, wherein the second plate of the silicon capacitor fills the deep trench; and
forming a second plate of the high-voltage capacitor over a top interlayer dielectric layer among the one or more interlayer dielectric layers.

2. The method for manufacturing the semiconductor device according to claim 1, forming the first plate of the high-voltage capacitor comprises:
providing a substrate, and forming a bottom interlayer dielectric layer among the one or more interlayer dielectric layers over the substrate;
forming a first metal layer covering a part of the bottom interlayer dielectric layer;
forming a first interlayer dielectric layer among the one or more interlayer dielectric layers, wherein the first interlayer dielectric layer covers the first metal layer and the bottom interlayer dielectric layer; and forming a conductive via in the first interlayer dielectric layer, wherein the conductive via is connected to the first metal layer; and
forming a second metal layer, wherein the second metal layer covers a part of the first interlayer dielectric layer, the second metal layer is connected to the first metal layer through the conductive via, and the second metal layer serves as a first plate of the high-voltage capacitor.

3. The method for manufacturing the semiconductor device according to claim 2, wherein when viewed along a direction perpendicular to the substrate, the first plate of the high-voltage capacitor covers a part of the first metal layer.

4. The method for manufacturing the semiconductor device according to claim 2, wherein all the interlayer dielectric layers are etched to form the deep trench, wherein the deep trench exposes the first metal layer, and the first plate of the silicon capacitor is connected with the first plate of the high-voltage capacitor through the first metal layer.

5. The method for manufacturing the semiconductor device according to claim 2, wherein etching the one or more interlayer dielectric layers to form the deep trench comprises:
forming a photoresist layer on the top interlayer dielectric layer;
exposing and developing the photoresist layer to form a patterned photoresist layer;
etching all the interlayer dielectric layers with the patterned photoresist layer as a mask until the first metal layer is exposed; and
removing the patterned photoresist layer.

6. The method for manufacturing the semiconductor device according to claim 2, wherein materials of the first plate and the second plate of the high-voltage capacitor comprise copper, tungsten, aluminum, ruthenium or cobalt, materials of the one or more interlayer dielectric layers other than the top interlayer dielectric layer comprise ethyl silicate, boro-phospho-silicate glass or a low dielectric constant material, and materials of the top interlayer dielectric layer comprise one or more of silicon oxynitride and silicon nitride; materials of the first plate of the silicon capacitor comprise titanium nitride, materials of the second plate of the silicon capacitor comprise tungsten, and the dielectric layers of the silicon capacitor comprise a silicon nitride layer or a stacked structure comprising a silicon oxide layer, a silicon nitride layer, and another silicon oxide layer.

7. The method for manufacturing the semiconductor device according to claim 4, wherein conductive vias are formed in the interlayer dielectric layers, wherein each of the interlayer dielectric layers has one or more of the conductive vias formed therein, and the conductive vias are connected with each other and connected to the first plate of the high-voltage capacitor, wherein additional metal layers are formed in one-to-one correspondence with the interlayer dielectric layers over the first plate of the high-voltage capacitor, each of the additional metal layers is connected with two adjacent ones of the conductive vias, and the additional metal layers and the conductive vias jointly form a lead-out channel of the first plate of the high-voltage capacitor.

8. The method for manufacturing the semiconductor device according to claim 7, wherein the substrate comprises a first region and a second region, a semiconductor structure is formed in the second region, and the high-voltage capacitor and the silicon capacitor are formed in the first region; wherein the method further comprises:
forming interlayer dielectric layers of the second region, and forming a metal layer of the second region and a conductive via of the second region for each of the interlayer dielectric layers of the second region, wherein the metal layer and the conductive via of the second region lead out a corresponding electrode of the semiconductor structure;
wherein the first plate of the high-voltage capacitor is formed synchronously with the metal layer of the second region in the same layer, each of the dielectric layers of the high-voltage capacitor is formed synchronously with one of the interlayer dielectric layers of the second region located in the same layer, and the lead-out channel is formed synchronously with the metal layer and the conductive via of the second region in the same layer.

9. The method for manufacturing the semiconductor device according to claim 8, wherein a lead-out terminal of the first plate of the high-voltage capacitor, a lead-out terminal of the first plate of the silicon capacitor, and a lead-out terminal of the second plate of the silicon capacitor are formed while the second plate of the high-voltage capacitor is formed;
wherein forming the second plate of the high-voltage capacitor over the top interlayer dielectric layer comprises:
forming a conductive material layer covering the top interlayer dielectric layer; and
etching the conductive material layer until a part of the top interlayer dielectric layer is exposed, retaining the conductive material layer directly above the first plate of the high-voltage capacitor as the second plate of the high-voltage capacitor, retaining the conductive material layer on the lead-out channel as a first lead-out terminal, the first lead-out terminal leading out the first plate of the high-voltage capacitor and the first plate of the silicon capacitor, respectively, and retaining the conductive material layer on the second plate of the silicon capacitor as a second lead-out terminal, the second lead-out terminal leading out the second plate of the silicon capacitor.

10. The method for manufacturing the semiconductor device according to claim 4, wherein the first plate of the silicon capacitor extends from the sidewall of the deep trench to the top interlayer dielectric layer and serves as a lead-out electrode of the first plate of the silicon capacitor.

11. The method for manufacturing the semiconductor device according to claim 10, wherein a lead-out terminal of the first plate of the high-voltage capacitor, a lead-out terminal of the first plate of the silicon capacitor, and a lead-out terminal of the second plate of the silicon capacitor are formed while the second plate of the high-voltage capacitor is formed;
wherein forming the second plate of the high-voltage capacitor over the top interlayer dielectric layer comprises:
forming a conductive material layer covering the top interlayer dielectric layer; and
etching the conductive material layer until a part of the top interlayer dielectric layer is exposed, retaining the conductive material layer directly above the first plate of the high-voltage capacitor as the second plate of the high-voltage capacitor, retaining the conductive material layer on the lead-out electrode as a first lead-out terminal, the first lead-out terminal leading out the first plate of the high-voltage capacitor and the first plate of the silicon capacitor, respectively, and retaining the conductive material layer on the second plate of the silicon capacitor as a second lead-out terminal, the second lead-out terminal leading out the second plate of the silicon capacitor.

12. The method for manufacturing the semiconductor device according to claim 2, wherein forming the one or more interlayer dielectric layers over the first plate of the high-voltage capacitor as the dielectric layers of the high-voltage capacitor comprises:
forming a second interlayer dielectric layer, wherein the second interlayer dielectric layer covers the first plate of the high-voltage capacitor and the first interlayer dielectric layer; and
forming the top interlayer dielectric layer over the second interlayer dielectric layer.

13. A semiconductor device manufactured by the method for manufacturing the semiconductor device according to claim 1, wherein the semiconductor device comprises:
a first plate of a high-voltage capacitor;
one or more interlayer dielectric layers, located over the first plate of the high-voltage capacitor and serving as dielectric layers of the high-voltage capacitor, wherein a deep trench extends through the interlayer dielectric layers;
a first plate of a silicon capacitor, formed on a sidewall and a bottom of the deep trench, wherein the first plate of the silicon capacitor is connected with the first plate of the high-voltage capacitor;
a dielectric layer of the silicon capacitor, formed on the sidewall and the bottom of the deep trench, wherein the dielectric layer of the silicon capacitor covers the first plate of the silicon capacitor;
a second plate of the silicon capacitor, formed in the deep trench and filling the deep trench; and
a second plate of the high-voltage capacitor, over the top interlayer dielectric layer.

14. The semiconductor device according to claim 13, wherein conductive vias are formed in the interlayer dielectric layers, wherein each of the interlayer dielectric layers has one or more of the conductive vias formed therein, and the conductive vias in the interlayer dielectric layers are connected with each other and connected to the first plate of the high-voltage capacitor, forming a lead-out channel of the first plate of the high-voltage capacitor.

15. The semiconductor device according to claim 13, wherein the first plate of the silicon capacitor extends from the sidewall of the deep trench to the top interlayer dielectric layer and serves as a lead-out electrode of the first plate of the silicon capacitor.
